(19) United States
(12) Patent Application Publication
(10) Pub. No.: US 2017/0010594 A1
(43) Pub. Date: Jan. 12, 2017

(54) PRECISION POSITION ENCODER/SENSOR USING NITROGEN VACANCY DIAMOND

(71) Applicant: Lockheed Martin Corporation, Bethesda, MD (US)

(72) Inventors: Anjaney Pramod KOTTAPALLI, San Jose, CA (US); Gary Edward MONTGOMERY, Palo Alto, CA (US); Margaret Miller SHAW, Silver Spring, MD (US); John B. Stetson, JR., New Hope, PA (US)

(73) Assignee: Lockheed Martin Corporation, Bethesda, MD (US)

(21) Appl. No.: 15/003,652

(22) Filed: Jan. 21, 2016

Related U.S. Application Data
(60) Provisional application No. 62/190,209, filed on Jul. 8, 2015.

(51) Int. Cl. G05B 19/042; G01R 33/032; G01D 5/14

(52) U.S. Cl. CPC G05B 19/042; G01D 5/14; G01R 33/032; G05B 2219/25317

(57) ABSTRACT

A position sensor system includes a position encoder component and a magnetic field sensor. The magnetic field sensor may be a diamond nitrogen vacancy material magnetic field sensor, and may be capable of resolving a magnetic field vector.

### CROSS-REFERENCE TO RELATED PATENT APPLICATIONS

This application claims priority to U.S. Provisional Application No. 62/190,209, filed on Jul. 8, 2015, the entirety of which is incorporated herein by reference.

### BACKGROUND

The present disclosure generally relates to a method and system for sensing the position of an element. Pre-existing position sensing systems, such as optoelectronic position sensor systems or Hall effect sensor systems, provide discrete position information for an object. The precision of optoelectronic position sensing systems is limited by the minimum optical diffraction grating size and pixel size of the optical sensor. Optoelectronic and Hall effect sensors do not provide the ability to proportionally determine the location between the discrete positions of the optical diffraction gratings. This lack of proportional sensing reduces the precision of the sensor system and may lead to undesirable jitter and instability when the sensor is utilized in a closed loop arrangement and the desired position is located between discrete optical grating positions. Additionally, the volume of optoelectronic position sensors becomes large when a high degree of precision is achieved. Thus, there is a need for a high precision position sensor system capable of proportional sensing and having a small volume.

### SUMMARY

Some embodiments relate to a position sensor. The position sensor may comprise a first magnetic field sensor, a second magnetic field sensor, and a position encoder component comprising a magnetic region configured to produce a magnetic field gradient from a first end of the magnetic region to the second end of the magnetic region. The first magnetic field sensor and the second magnetic field sensor are separated by a distance that is less than a length of the magnetic region. At least one of the first magnetic sensor and the second magnetic sensor may comprise a nitrogen vacancy (NV) diamond magnetic field sensor. The magnetic region may comprise a ferromagnetic component having a cross-section at the first end of the magnetic region that is smaller than a cross-section at the second end of the magnetic region. The magnetic region may comprise a magnetic polymer having a magnetic particle concentration at the first end of the magnetic region that is smaller than a magnetic particle concentration at the second end of the magnetic region. The position sensor may further comprise a third magnetic field sensor and a fourth magnetic field sensor. The position encoder component may be a rotary position encoder. The position encoder component may be a linear position encoder. The position encoder component may further comprise a plurality of the magnetic regions configured to produce a magnetic field gradient from a first end of the magnetic region to the second end of the magnetic region arranged end to end on the position encoder component.

Other embodiments relate to a position sensor system. The position sensor system may comprise a position encoder component comprising a magnetic region configured to produce a magnetic field gradient from a first end of the magnetic region to the second end of the magnetic region, a first magnetic field sensor, a second magnetic field sensor, and a controller. The first magnetic field sensor and the second magnetic field sensor are separated by a distance that is less than a length of the magnetic region. The controller may be configured to determine a direction and magnitude of a change in position of the position encoder component based on the output of the first magnetic field sensor and the second magnetic field sensor. The controller may be further configured to determine a position of the position encoder component based on an initial position of the position encoder component and the direction and magnitude of the change in position of the position encoder component.

Other embodiments relate to a position control system. The position control system may comprise a position encoder component comprising a magnetic region configured to produce a magnetic field gradient from a first end of the magnetic region to the second end of the magnetic region, an actuator coupled to the position encoder component, a first magnetic field sensor, a second magnetic field sensor, wherein the first magnetic field sensor and the second magnetic field sensor are separated by a distance that is less than a length of the magnetic region, and a controller. The controller may be configured to control the actuator to produce a change in position of the position encoder component, and determine a direction and magnitude of the change in position of the position encoder component based on the output of the first magnetic field sensor and the second magnetic field sensor. The controller may be further configured to control the actuator to stop a change in position of the position encoder component when a desired change in position of the position encoder component has been achieved. The controller may be further configured to determine the position of the position encoder component after the change in position of the position encoder component produced by the actuator is complete.

Other embodiments relate to a method of controlling position. The method may comprise activating an actuator coupled to a position encoder component to produce a change in position of the position encoder component, wherein the position encoder component comprises a magnetic region configured to produce a magnetic field gradient from a first end of the magnetic region to the second end of the magnetic region; determining a direction and magnitude of the change in position of the position encoder component based on the output of a first magnetic field sensor and a second magnetic field sensor, wherein the first magnetic field sensor and the second magnetic field sensor are separated by a distance that is less than a length of the magnetic region; and deactivating the actuator to stop the change in position of the position encoder component when a desired position of the position encoder component is reached. The method may further comprise determining the position of the position encoder element after deactivating the actuator.

Other embodiments relate to a position sensor. The position sensor comprises a first magnetic field sensor, a second magnetic field sensor, and a position encoder component comprising a plurality of uniform magnetic regions, wherein the uniform magnetic regions have a uniform spacing therebetween, and the first magnetic field sensor and the second magnetic field sensor are separated by a distance that is less than the uniform spacing between the uniform magnetic regions. At least one of the first magnetic sensor and the second magnetic sensor may comprise a nitrogen vacancy (NV) diamond magnetic field sensor. The position sensor may further comprise a third magnetic field sensor and a fourth magnetic field sensor. The position encoder component may be a rotary position encoder. The position encoder component may be a linear position encoder. The position encoder component may further comprise a magnetic region configured to produce a magnetic field gradient from a first end of the magnetic region to the second end of the magnetic region disposed between each of the plurality of uniform magnetic regions. The magnetic region may comprise a ferromagnetic component having a cross-section at the first end of the magnetic region that is smaller than a cross-section at the second end of the magnetic region. The magnetic region may comprise a magnetic polymer having a magnetic particle concentration at the first end of the magnetic region that is smaller than a magnetic particle concentration at the second end of the magnetic region.

Other embodiments relate to a position sensor system. The position sensor system may comprise a position encoder component comprising a plurality of uniform magnetic regions, wherein the uniform magnetic regions have a uniform spacing therebetween, a first magnetic field sensor, a second magnetic field sensor, wherein the first magnetic field sensor and the second magnetic field sensor are separated by a distance that is less than the uniform spacing between the uniform magnetic regions, and a controller. The controller may be configured to determine a direction and magnitude of a change in position of the position encoder component based on the output of the first magnetic field sensor and the second magnetic field sensor. The controller may be further configured to determine a position of the position encoder component based on an initial position of the position encoder component and the direction and magnitude of the change in position of the position encoder component.

Other embodiments relate to a position control system. The position control system may comprise a position encoder component comprising a plurality of uniform magnetic regions, wherein the uniform magnetic regions have a uniform spacing therebetween, an actuator coupled to the position encoder component, a first magnetic field sensor, a second magnetic field sensor, wherein the first magnetic field sensor and the second magnetic field sensor are separated by a distance that is less than the uniform spacing between the uniform magnetic regions, and a controller. The controller may be configured to control the actuator to produce a change in position of the position encoder component, determine a direction and magnitude of the change in position of the position encoder component based on the output of the first magnetic field sensor and the second magnetic field sensor. The controller may be further configured to control the actuator to stop a change in position of the position encoder component when a desired change in position of the position encoder component has been achieved. The controller may be further configured to determine the position of the position encoder component after the change in position of the position encoder component produced by the actuator is complete.

Other embodiments relate to a method of controlling position. The method comprises activating an actuator coupled to a position encoder component to produce a change in position of the position encoder component, wherein the position encoder component comprises a plurality of uniform magnetic regions, wherein the uniform magnetic regions have a uniform spacing therebetween; determining a direction and magnitude of the change in position of the position encoder component based on the output of a first magnetic field sensor and a second magnetic field sensor, wherein the first magnetic field sensor and the second magnetic field sensor are separated by a distance that is less than the uniform spacing between the uniform magnetic regions; and deactivating the actuator to stop the change in position of the position encoder component when a desired position of the position encoder component is reached. The method may further comprise determining the position of the position encoder element after deactivating the actuator.

Other embodiments relate to a position sensor. The position sensor may comprise a first magnetic field sensor, a second magnetic field sensor, and a position encoder component comprising a plurality of uniform magnetic regions and a plurality of tapered magnetic regions, wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions. At least one of the first magnetic sensor and the second magnetic sensor may comprise a nitrogen vacancy (NV) diamond magnetic field sensor. The tapered magnetic regions may comprise a ferromagnetic component having a cross-section at the first end of the tapered magnetic regions that is smaller than a cross-section at the second end of the tapered magnetic regions. The tapered magnetic regions may comprise a magnetic polymer having a magnetic particle concentration at the first end of the tapered magnetic regions that is smaller than a magnetic particle concentration at the second end of the tapered magnetic regions. The position sensor may further comprise a third magnetic field sensor and a fourth magnetic field sensor. The position encoder component may be a rotary position encoder. The position encoder component may be a linear position encoder.

Other embodiments relate to a position sensor system. The system may comprise a position encoder component comprising a plurality of uniform magnetic regions and a plurality of tapered magnetic regions, wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions, a first magnetic field sensor, a second magnetic field sensor, wherein the first magnetic field sensor and the second magnetic field sensor are separated by a distance that is less than the uniform spacing between the uniform magnetic regions, and a controller. The controller may be configured to determine a direction and magnitude of a change in position of the position encoder component based on the output of the first magnetic field sensor and the second magnetic field sensor. The controller may be further configured to determine a position of the position encoder component based on an initial position of the position encoder component and the direction and magnitude of the change in position of the position encoder component.

Other embodiments relate to a position control system. The system may comprise a position encoder component comprising a plurality of uniform magnetic regions and a plurality of tapered magnetic regions, wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions, an actuator coupled to the position encoder component, a first magnetic field sensor, a second magnetic field sensor, wherein the first magnetic field sensor and the second magnetic field sensor are separated by a distance that is less than the uniform spacing between the uniform magnetic regions, and a controller. The controller may be configured to control the actuator to produce a change in position of the position encoder component and determine a direction and magnitude of the change in position of the position encoder component based on the output of the first magnetic field sensor and the second magnetic field sensor. The controller may be further configured to control the actuator to stop a change in position of the position encoder component when a desired change in position of the position encoder component has been achieved. The controller may be further configured to determine the position of the position encoder component after the change in position of the position encoder component produced by the actuator is complete.

Other embodiments relate to a method of controlling position. The method may comprise activating an actuator coupled to a position encoder component to produce a change in position of the position encoder component, wherein the position encoder component comprises a plurality of uniform magnetic regions and a plurality of tapered magnetic regions, wherein the uniform magnetic regions have a uniform distance therebetween, and the tapered magnetic regions are configured to produce a magnetic field gradient from a first end of the magnetic region to the second end of the magnetic region; determining a direction and magnitude of the change in position of the position encoder component based on the output of a first magnetic field sensor and a second magnetic field sensor, wherein the first magnetic field sensor and the second magnetic field sensor are separated by a distance that is less than the uniform spacing between the uniform magnetic regions; and deactivating the actuator to stop the change in position of the position encoder component when a desired position of the position encoder component is reached. The method may further comprise determining the position of the position encoder element after deactivating the actuator.

### BRIEF DESCRIPTION OF THE DRAWINGS

FIG. 1 illustrates one orientation of a NV center in a diamond lattice.

FIG. 2 is an energy level diagram illustrates energy levels of spin states for the NV center.

FIG. 3 is a schematic illustrating a NV center magnetic sensor system.

FIG. 4 is a graph illustrating the fluorescence as a function of applied RF frequency of an NV center along a given direction for a zero magnetic field and a non-zero magnetic field.

FIG. 5 is a graph illustrating the fluorescence as a function of applied RF frequency for four different NV center orientations for a non-zero magnetic field.

FIG. 6 is a schematic illustrating a NV center magnetic sensor system according to some embodiments.

FIG. 7 is a schematic illustrating a position sensor system according to some embodiments.

FIG. 8 is a schematic illustrating a position sensor system including a rotary position encoder.

FIG. 9 is a schematic illustrating a top down view of a rotary position encoder.

FIG. 10 is a schematic illustrating a position sensor system including a linear position encoder.

FIG. 11 is a schematic illustrating a magnetic element arrangement of a position encoder according to some embodiments.

FIG. 12 is a schematic illustrating a magnetic element arrangement of a position encoder according to other embodiments.

FIG. 13 is a schematic illustrating a magnetic element arrangement of a position encoder according to other embodiments.

FIG. 14 is a schematic illustrating the relationship of a position sensor head and the magnetic elements of a position encoder.

FIG. 15 is a graph of measured magnetic field intensity attributable to magnetic elements of a position encoder for a first magnetic field sensor and a second magnetic field sensor of a position sensor head.

FIG. 16 is a flow chart illustrating the process of determining a position utilizing a position sensor system according to some embodiments.

### DETAILED DESCRIPTION

Position sensor systems as described herein that include magnetic field sensors may provide a high degree of precision, proportional sensing capability, small volume, and low power requirements. The magnetic field sensor systems may include magneto-optical defect center materials, such as diamond containing nitrogen vacancies, and may resolve a magnetic field vector. The position sensor systems may detect rotary or linear positions. Additionally, magnetic field sensors in combination with an appropriate position encoder including appropriate magnetic regions may allow the position sensor to proportionally sense position between discrete positions of the position encoder. The position sensor systems also provide a fast sample rate, on the order of 2 MHz.

NV Center, its Electronic Structure, and Optical and RF Interaction

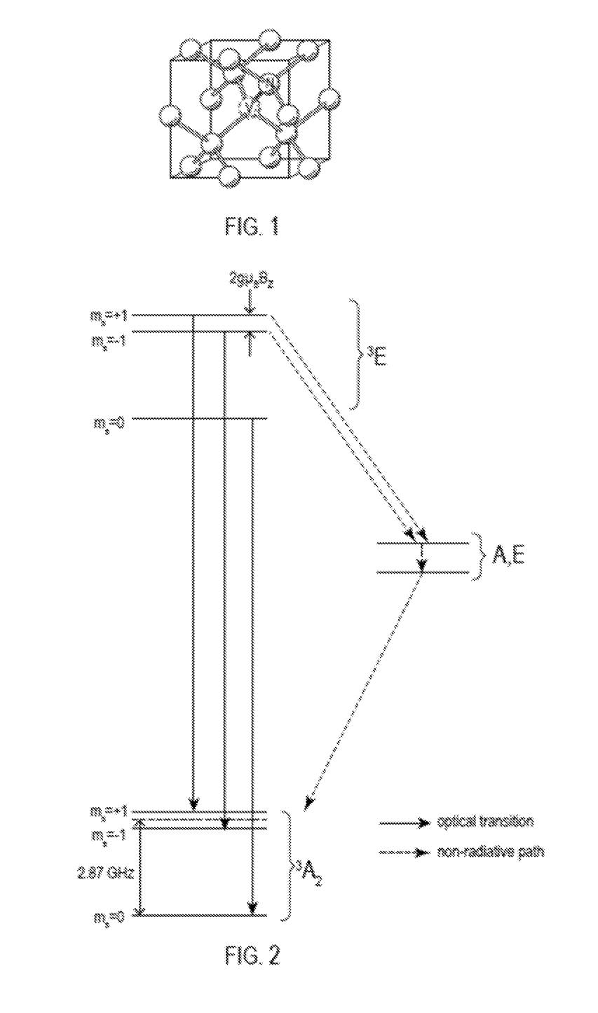

The nitrogen vacancy (NV) center in diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. Conventionally, the neutral charge state uses the nomenclature NV⁰, while the negative charge state uses the nomenclature NV, which is adopted in this description.

The NV center has a number of electrons including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels mₛ=±1 by an amount 2gμ_{B}Bz, where g is the g-factor, μ_{B} is the Bohr magneton, and Bz is the component of the external magnetic field along the NV axis. This relationship is correct for a first order and inclusion of higher order corrections is a straight forward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states which have the same spin. For a direct transition between the excited triplet ³E and the ground state ³A₂, a photon of red light is emitted with a photon energy corresponding to the energy difference between the energy levels of the transitions.

There is, however, an alternate non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than that from the mₛ=0 spin state of the excited triplet ³E to the intermediate energy levels. The transition from the singlet states A, E to the ground state triplet ³A₂ predominantly decays to the mₛ=0 spin state over the mₛ=±1 spin states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

NV Center, or Magneto-Optical Defect Center, Magnetic Sensor System

FIG. 3 is a schematic illustrating a NV center magnetic sensor system 300 which uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation to an NV diamond material 320 with NV centers. The system 300 further includes an RF excitation source 330 which provides RF radiation to the NV diamond material 320. Light from the NV diamond may be directed through an optical filter 350 to an optical detector 340.

The RF excitation source 330 may be a microwave coil, for example. The RF excitation source 330 when emitting RF radiation with a photon energy resonant with the transition energy between ground mₛ=0 spin state and the mₛ=+1 spin state excites a transition between those spin states. For such a resonance, the spin state cycles between ground mₛ=0 spin state and the mₛ=+1 spin state, reducing the population in the mₛ=0 spin state and reducing the overall fluorescence at resonance. Similarly resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state. At resonance between the mₛ=0 spin state and the mₛ=−1 spin state, or between the mₛ=0 spin state and the mₛ=+1 spin state, there is a decrease in the fluorescence intensity.

The optical excitation source 310 may be a laser or a light emitting diode, for example, which emits light in the green, for example. The optical excitation source 310 induces fluorescence in the red, which corresponds to an electronic transition from the excited state to the ground state. Light from the NV diamond material 320 is directed through the optical filter 350 to filter out light in the excitation band (in the green for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

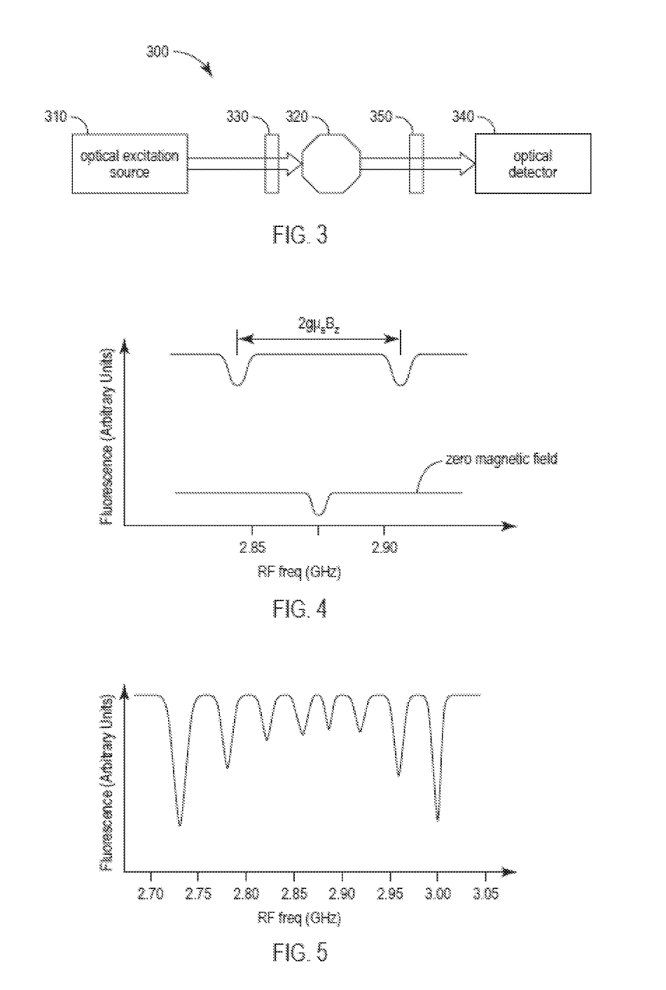

For continuous wave excitation, the optical excitation source 310 continuously pumps the NV centers, and the RF excitation source 330 sweeps across a frequency range which includes the zero splitting (when the mₛ=±1 spin states have the same energy) photon energy of 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples, of pulsed excitation schemes include Ramsey pulse sequence, and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results along with the known orientation of crystallographic planes of a diamond lattice allows not only the magnitude of the external magnetic field to be determined, but also the direction of the magnetic field.

While FIG. 3 illustrates an NV center magnetic sensor system 300 with NV diamond material 320 with a plurality of NV centers, in general the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

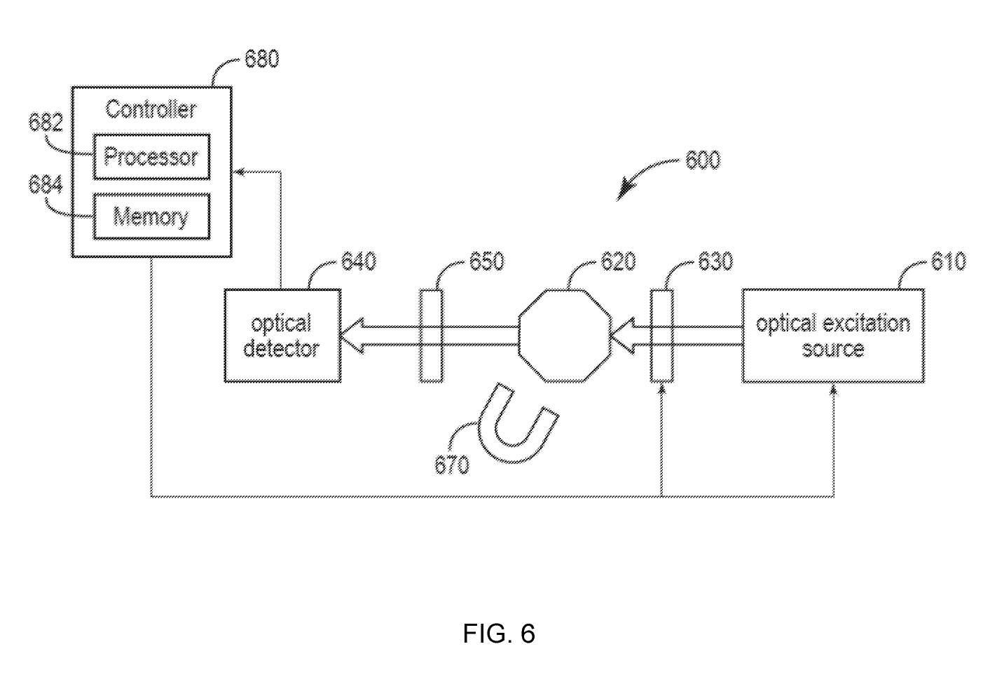

FIG. 6 is a schematic of an NV center magnetic sensor 600, according to some embodiments. The sensor 600 includes an optical excitation source 610, which directs optical excitation to an NV diamond material 620 with NV centers, or another magneto-optical defect center material with magneto-optical defect centers. An RF excitation source 630 provides RF radiation to the NV diamond material 620. The NV center magnetic sensor 600 may include a bias magnet 670 applying a bias magnetic field to the NV diamond material 620. Light from the NV diamond material 620 may be directed through an optical filter 650 and an electromagnetic interference (EMI) filter 660, which suppresses conducted interference, to an optical detector 640. The sensor 600 further includes a controller 680 arranged to receive a light detection signal from the optical detector 640 and to control the optical excitation source 610 and the RF excitation source 630.

The RF excitation source 630 may be a microwave coil, for example. The RF excitation source 630 is controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green, for example. The optical excitation source 610 induces fluorescence in the red, which corresponds to an electronic transition from the excited state to the ground state. Light from the NV diamond material 620 is directed through the optical filter 650 to filter out light in the excitation band (in the green for example), and to pass light in the red fluorescence band, which in turn is detected by the optical detector 640. The EMI filter 660 is arranged between the optical filter 650 and the optical detector 640 and suppresses conducted interference. The optical excitation light source 610, in addition to exciting fluorescence in the NV diamond material 620, also serves to reset the population of the mₛ=0 spin state of the ground state ³A₂ to a maximum polarization, or other desired polarization.

The controller 680 is arranged to receive a light detection signal from the optical detector 640 and to control the optical excitation source 610 and the RF excitation source 630. The controller may include a processor 682 and a memory 684, in order to control the operation of the optical excitation source 610 and the RF excitation source 630. The memory 684, which may include a nontransitory computer readable medium, may store instructions to allow the operation of the optical excitation source 610 and the RF excitation source 630 to be controlled.

According to some embodiments of operation, the controller 680 controls the operation such that the optical excitation source 610 continuously pumps the NV centers of the NV diamond material 620. The RF excitation source 630 is controlled to continuously sweep across a frequency range which includes the zero splitting (when the mₛ=±1 spin states have the same energy) photon energy of 2.87 GHz. When the photon energy of the RF radiation emitted by the RF excitation source 630 is the difference in energies of the mₛ=0 spin state and the mₛ=−1 or mₛ=+1 spin state, the overall fluorescence intensity is reduced at resonance, as discussed above with respect to FIG. 3. In this case, there is a decrease in the fluorescence intensity when the RF energy resonates with an energy difference of the mₛ=0 spin state and the mₛ=−1 or mₛ=+1 spin states. In this way the component of the magnetic field Bz along the NV axis may be determined by the difference in energies between the mₛ=−1 and the mₛ=+1 spin states.

As noted above, the diamond material 620 will have NV centers aligned along directions of four different orientation classes, and the component Bz along each of the different orientations may be determined based on the difference in energy between the mₛ=−1 and the mₛ=+1 spin states for the respective orientation classes. In certain cases, however, it may be difficult to determine which energy splitting corresponds to which orientation class, due to overlap of the energies, etc. The bias magnet 670 provides a magnetic field, which is preferably uniform on the NV diamond material 620, to separate the energies for the different orientation classes, so that they may be more easily identified.

Position Sensor Including Magnetic Field Sensor

A position sensor system may include a position sensor that includes a magnetic field sensor. The magnetic field sensor may be a DNV magnetic field sensor capable of resolving a magnetic field vector of the type described above. The high sensitivity of the DNV magnetic field sensor combined with an appropriate position encoder component is capable of resolving both a discrete position and a proportionally determined position between discrete positions. The position sensor system has a small size, light weight, and low power requirement.

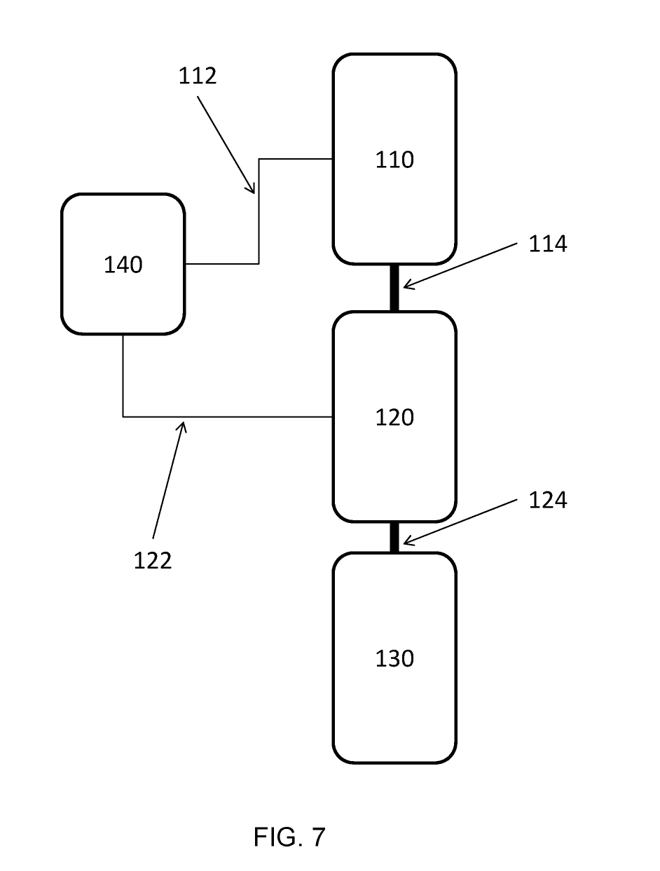

As shown in FIG. 7, the position sensor 120 may be part of a system that also includes an actuator 110 and a sensor component 130. The actuator 110 may be connected to the position sensor 120 by any appropriate attachment means 114, such as a rod or shaft. The actuator may be any actuator that produces the desired motion, such as an electro-mechanical actuator. The position sensor 120 may be connected to the sensor component 130 by any appropriate attachment means 124, such as a rod or shaft. A controller 140 may be included in the system and connected to the position sensor 120 and optionally the actuator 110 by electronic interconnects 122 and 112, respectively. The controller may be configured to receive a measured position from the position sensor 120 and activate or deactivate the actuator to position the sensor 130 in a desired position. According to some embodiments, the controller may be on the same substrate as the magnetic field sensor of the position sensor. The controller may include a processor and a memory.

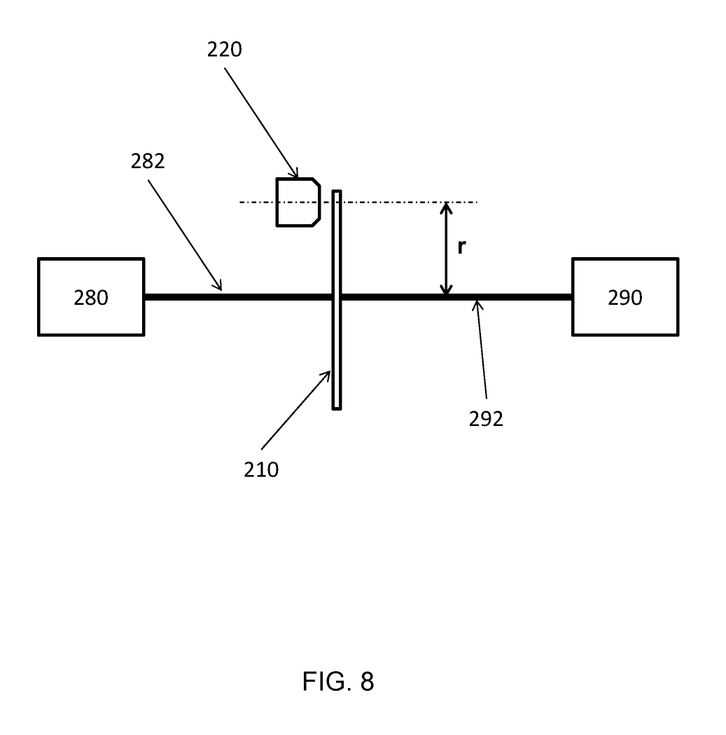

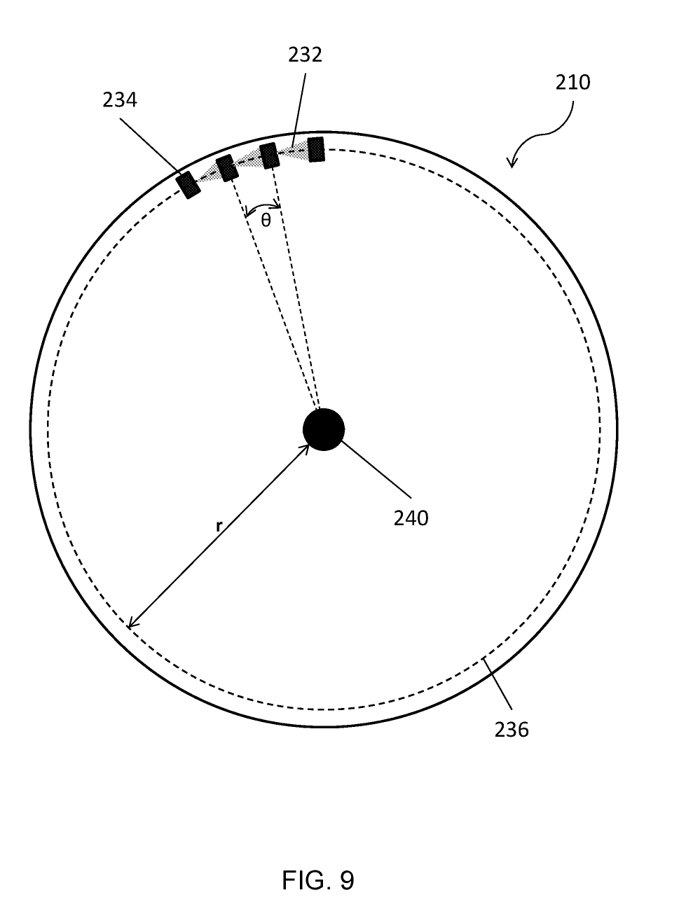

The position sensor may be a rotary position sensor. FIG. 8 depicts a rotary position sensor system that includes a rotary actuator 280 that is configured to produce a rotation of a sensor 290. A rotary position encoder 210 is connected to the rotary actuator 280 by a connection means 282, such as a rod or shaft. A connection means 292 is also provided between the rotary position encoder 210 and the sensor 290. A position sensor head 220 is located to measure the magnetic field of magnetic elements located on the rotary position encoder 210. The position sensor head 220 is aligned with magnetic elements located on the rotary position encoder 210 at a distance, r, from the center of the rotary position encoder. A surface of the rotary position encoder 210 that includes magnetic elements is shown in FIG. 9. The center 240 of the rotary position encoder 210 may be configured to attach to a connection means 292, 294 that connects the rotary position encoder 210 to the actuator 208 or the sensor 290. Magnetic elements, such as uniform coarse magnetic elements 234 and tapered fine magnetic elements 232, may be disposed on the surface of the rotary position encoder 210 along an arc 236 at a distance, r, from the center of the rotary position encoder. The magnetic elements on the rotary position encoder 210 may be located on only a portion of the arc, as shown in FIG. 9, or around an entirety of the arc forming a circle of magnetic elements.

The spacing between the magnetic elements on the rotary position encoder 210 correlates to a discrete angular rotation, θ. The distance between magnetic elements associated with the discrete angular rotation, θ, increases as r increases. The sensitivity of the magnetic field sensors employed in the position sensor allows r to be reduced while maintaining a high degree of precision for the angular position of the rotary position encoder. The rotary position encoder may have an r on the order of mm, such as an r of 1 mm to about 30 mm, or about 5 mm to about 20 mm. The rotary position encoder allows for the measurement of a rotary position with a precision of 0.5 micro-radians.

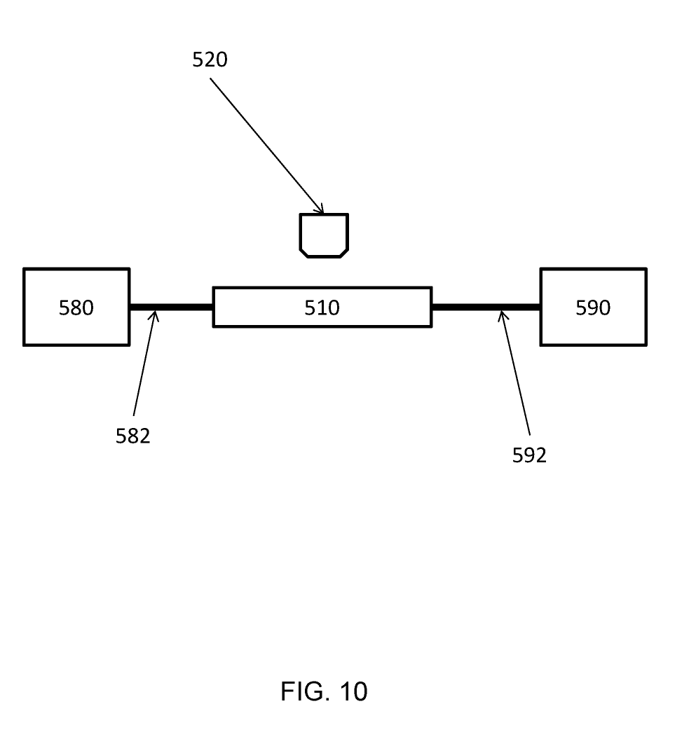

The position sensor may be a linear position sensor. As shown in FIG. 10, the linear position sensor system includes a linear actuator 580 that is configured to produce linear motion of the linear position encoder 510 and sensor 590. The linear position encoder 510 may be connected to the linear actuator by a connecting means 582, such as a rod or shaft. The linear position encoder 510 may be connected to the sensor 590 by a connecting means 592, such as a rod or shaft. A position sensor head 520 is located to measure the magnetic field produced by magnetic elements disposed on the linear position encoder. In some cases, a mechanical linkage, such as a lever arm, may be utilized to multiply the change in position of the linear position encoder for an associated movement of the sensor. The linear position sensor may have a sensitivity that allows a change in position on the order of hundreds of nanometers to be resolved, such as a position change of 500 nm.

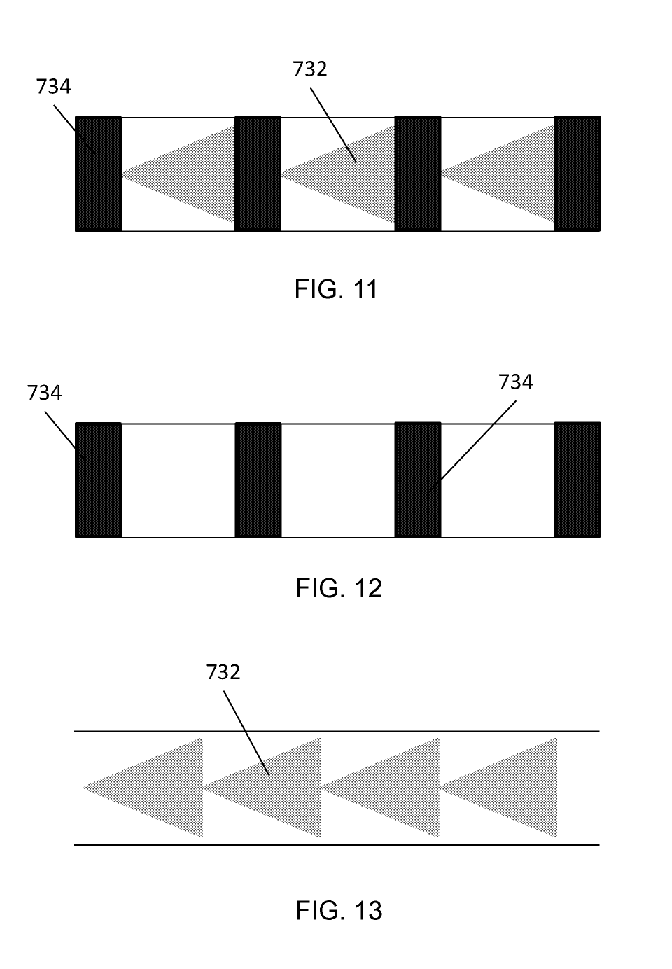

The magnetic elements may be arranged on the linear or rotary position encoder in any appropriate configuration. As shown in FIG. 11, the magnetic elements may include both uniform coarse magnetic elements 734 and tapered fine magnetic elements 732. The uniform coarse magnetic elements 734 may have an influence on the local magnetic field that is at least two orders of magnitude greater than the maximum influence of the tapered fine magnetic elements 734. The coarse magnetic elements 734 may be formed on the position encoder by any suitable process. According to some embodiments, a polymer loaded with magnetic material may be utilized to form the uniform coarse magnetic elements. The amount of magnetic material that may be included in the coarse magnetic elements is limited by potential interference with other elements in the system.

The tapered fine magnetic elements may be formed by any suitable process on the position encoder. According to some embodiments, a polymer loaded with magnetic material may be utilized to form the tapered fine magnetic elements. The loading of the magnetic material in the polymer may be increased to produce a magnetic field gradient from a first end of the tapered fine magnetic element to a second end of the tapered fine magnetic element. Alternatively, the geometric size of the tapered fine magnetic element may be increased to create the desired magnetic field gradient. A magnetic field gradient of the tapered fine magnetic element may be about 10 nT/mm. The tapered fine magnetic elements 732 as shown in FIG. 11 allow positions between the coarse magnetic elements 734 to be accurately resolved. The position encoder on which the magnetic elements are disposed may be formed from any appropriate material, such as a ceramic, glass, polymer, or non-magnetic metal material.

The size of the magnetic elements is limited by manufacturing capabilities. The magnetic elements on the position encoder may have geometric features on the order of nanometers, such as about 5 nm.

FIG. 12 depicts an alternate magnetic element arrangement that may be employed when the additional precision provided by the tapered fine magnetic elements is not required. The magnetic element arrangement of FIG. 12 includes only coarse magnetic elements 734. FIG. 13 depicts a magnetic element arrangement that does not include coarse magnetic elements. A similar effect to the coarse magnetic elements 734 may be achieved by utilizing the transitions between the maximum of the tapered fine magnetic elements 732 and the minimum of the adjacent tapered fine magnetic elements as indicators in much the same way that the coarse magnetic elements shown in FIGS. 11 and 12 indicate a discrete change in position. While FIGS. 11-13 depict the magnetic element arrangements in linear form, similar magnetic element arrangements may be applied to a rotary position encoder.

According to other embodiments, a single tapered magnetic element may be employed. Such an arrangement may be especially suitable for an application where only a small position range is required, as for a larger position range the increase in magnetic field with the increasing gradient of the magnetic element may interfere with other components of the position sensor system. The use of a single tapered magnetic element may allow a position to be determined without first initializing the position sensor by setting the position encoder to a known position. The ability of the magnetic field sensor to resolve a magnetic field vector may allow a single magnetic field sensor to be employed in the position sensor head when a single tapered fine magnetic element is utilized on the position encoder.

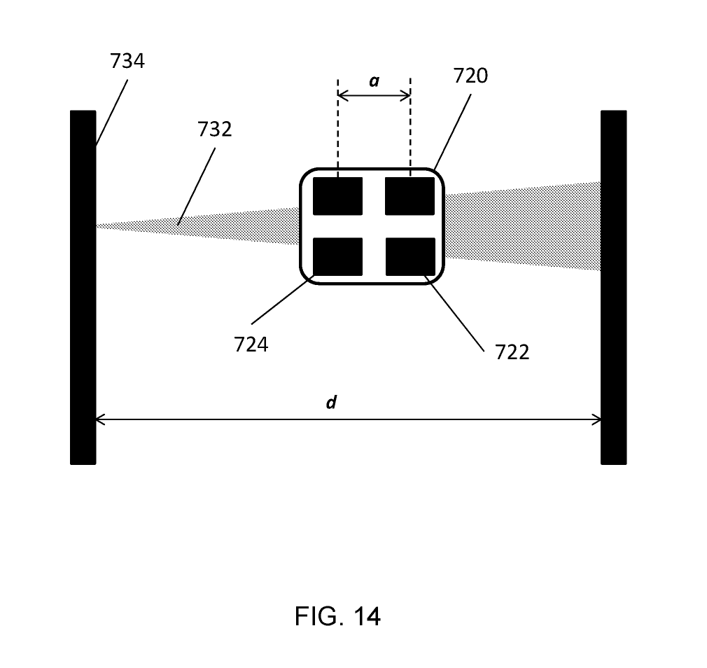

The position sensor head 720 may include a plurality of magnetic field sensors, as shown in FIG. 14. For magnetic element arrangements including more than one element, at least two magnetic field sensors 724 and 722 may be utilized in the position head sensor. The magnetic field sensors may be separated by a distance, a. The distance, a, between the magnetic sensors 722 and 724 may be less than the distance, d, between the coarse magnetic elements 734. According to some embodiments, the relationship between the spacing of the magnetic field sensors and the spacing of the coarse magnetic elements may be 0.1d<a<d. As shown in FIG. 14, the position sensor head 720 may include a third and fourth magnetic field sensor. The magnetic field sensors in the position sensor head may be DNV magnetic field sensors of the type described above.

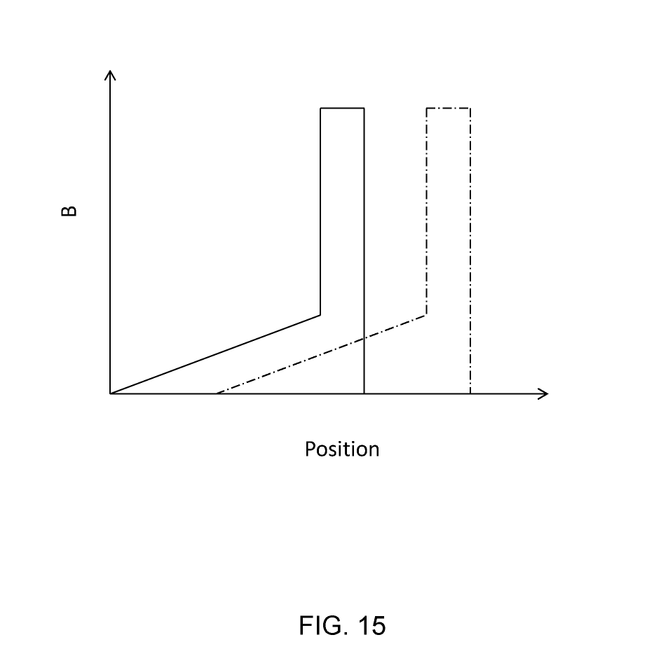

The magnetic field sensor arrangement in the position sensor head 720 depicted in FIG. 14 allows the direction of movement of the position encoder to be determined. As shown in FIG. 15, the spacing between the magnetic field sensors 724 and 722 produces a delayed response to the magnetic field elements as the position encoder moves. The difference in measured magnetic field for each magnetic field sensor allows a direction of the movement of the position encoder to be determined, as for any given position of the position encoder a different output magnetic field will be measured by each magnetic field sensor. The increasing portion of the plots in FIG. 15 is produced by the tapered fine magnetic element and the square peak is produced by the coarse magnetic element. These measured magnetic fields may be utilized to determine the change in position of the position encoder, and thereby the sensor connected to the position encoder.

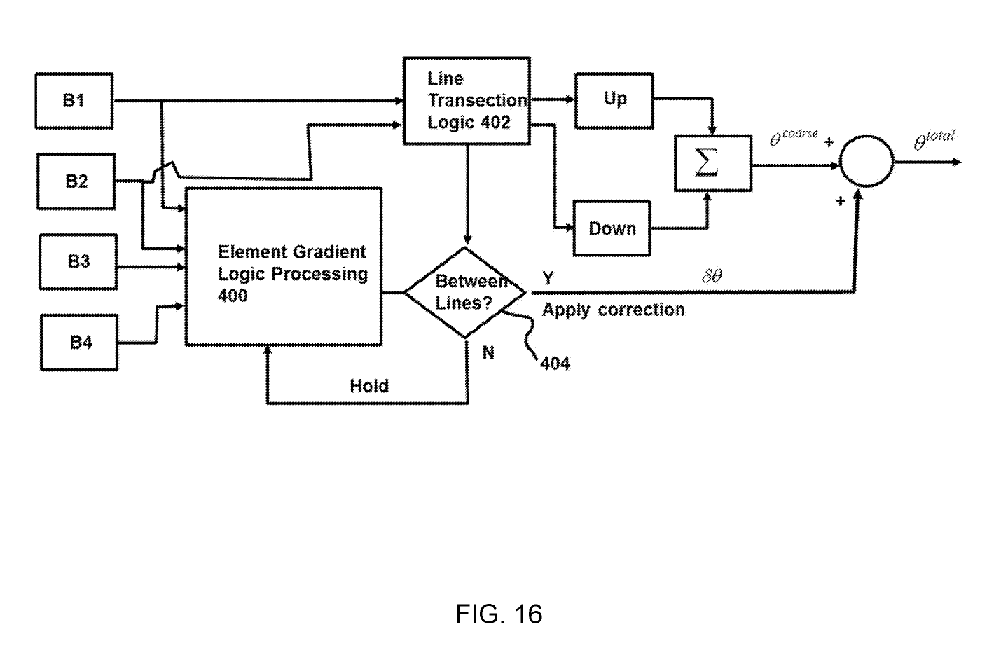

The controller of the position sensor system may be programmed to determine the position of position encoder, and thereby the sensor connected thereto, utilizing the output from the magnetic field sensors. As shown in FIG. 16, the controller may include a line transection logic 402 function that determines when the coarse magnetic elements have passed the magnetic sensor. The output from two magnetic field sensors B1 and B2 may be utilized to determine the direction of the position change based on the order in which a coarse magnetic element is encountered by the magnetic field sensors, and to count the number of coarse magnetic elements measured by the magnetic field sensors. Each coarse magnetic element adds a known amount of position change due to the known spacing between the coarse magnetic elements on the position encoder. An element gradient logic processing function 400 is programmed in the controller to determine the position between coarse magnetic elements based on the magnetic field signal produced by the tapered fine magnetic elements located between the coarse magnetic elements. As shown in FIG. 16, the element gradient logic processing 400 is utilized only when the line transection logic determines that the position is between coarse magnetic elements, or lines. In the case that the position is determined to be between coarse magnetic elements, a position correction, δθ, is calculated based on the magnetic field associated with the tapered fine magnetic elements. The position correction is then added to the sum of the position change calculated from the number of coarse magnetic elements that were counted. A final position may be calculated by adding the calculated position change to a starting position of the position encoder. The logic processing in the controller may be conducted by analog or digital circuits.

The position sensor may be employed in a method for controlling the position of the position encoder. The method includes determining a movement direction required to reach a desired position, and activating the actuator to produce the desired movement. The position sensor is employed to monitor the change in position of the position encoder, and determine when to deactivate the actuator and stop the change in position. The change in position may be stopped once the desired position is reached. The method may additionally include initializing the position sensor system by moving the position encoder to a known starting point. The end position of the position encoder may be determined after the deactivation of the actuator, and the end position may be stored in a memory of the position sensor controller as a starting position for future movement.

The ability of the position sensor system to resolve positions between the coarse magnetic elements of the position encoder provides many practical benefits. For example, the position of the position encoder, and associated sensor, may be known with more precision while reducing the size, weight and power requirements of the position sensor system. Additionally, position control systems that offer resolution of discrete position movements can result in dithering when a desired position is between two discrete position values. Dithering can result in unwanted vibration and overheating of the actuator as the control system repeatedly tries to reach the desired position.

The characteristics of the position sensor system described above make it especially suitable for applications where precision, size, weight, and power requirements are important considerations. The position sensor system is well suited for astronautic applications, such as on space vehicles. The position sensor system is also applicable to robot arms, 3-d mills, machine tools, and X-Y tables.

The position sensor system may be employed to control the position of a variety of sensors and other devices. Non-limiting examples of sensors that could be controlled with the position sensor system are optical sensors.

The embodiments of the concepts disclosed herein have been described in detail with particular reference to preferred embodiments thereof, but it will be understood by those skilled in the art that variations and modifications can be effected within the spirit and scope of the concepts.

What is claimed is:

1. A position sensor, comprising:
a first magnetic field sensor,
a second magnetic field sensor, and
a position encoder component comprising a magnetic region configured to produce a magnetic field gradient from a first end of the magnetic region to the second end of the magnetic region,
wherein the first magnetic field sensor and the second magnetic field sensor are separated by a distance that is less than a length of the magnetic region.

2. The position sensor of claim 1, wherein at least one of the first magnetic sensor and the second magnetic sensor comprise a nitrogen vacancy (NV) diamond magnetic field sensor.

3. The position sensor of claim 1, wherein the magnetic region comprises a ferromagnetic component having a cross-section at the first end of the magnetic region that is smaller than a cross-section at the second end of the magnetic region.

4. The position sensor of claim 1, wherein the magnetic region comprises a magnetic polymer having a magnetic particle concentration at the first end of the magnetic region that is smaller than a magnetic particle concentration at the second end of the magnetic region.

5. The position sensor of claim 1, further comprising a third magnetic field sensor and a fourth magnetic field sensor.

6. The position sensor of claim 1, wherein the position encoder component is a rotary position encoder.

7. The position sensor of claim 1, wherein the position encoder component is a linear position encoder.

8. The position sensor of claim 1, wherein the position encoder component further comprises a plurality of the magnetic regions configured to produce a magnetic field gradient from a first end of the magnetic region to the second end of the magnetic region arranged end to end on the position encoder component.

9. A position sensor system, comprising:
a position encoder component comprising a magnetic region configured to produce a magnetic field gradient from a first end of the magnetic region to the second end of the magnetic region,
a first magnetic field sensor,
a second magnetic field sensor, wherein the first magnetic field sensor and the second magnetic field sensor are separated by a distance that is less than a length of the magnetic region, and
a controller configured to:
determine a direction and magnitude of a change in position of the position encoder component based on the output of the first magnetic field sensor and the second magnetic field sensor.

10. The position sensor system of claim 9, wherein the controller is further configured to determine a position of the position encoder component based on an initial position of the position encoder component and the direction and magnitude of the change in position of the position encoder component.

11. A position control system, comprising:
a position encoder component comprising a magnetic region configured to produce a magnetic field gradient from a first end of the magnetic region to the second end of the magnetic region,
an actuator coupled to the position encoder component,
a first magnetic field sensor,
a second magnetic field sensor, wherein the first magnetic field sensor and the second magnetic field sensor are separated by a distance that is less than a length of the magnetic region, and
a controller configured to:
control the actuator to produce a change in position of the position encoder component,
determine a direction and magnitude of the change in position of the position encoder component based on the output of the first magnetic field sensor and the second magnetic field sensor.

12. The position control system of claim 11, wherein the controller is further configured to control the actuator to stop a change in position of the position encoder component when a desired change in position of the position encoder component has been achieved.

13. The position control system of claim 11, wherein the controller is further configured to determine the position of the position encoder component after the change in position of the position encoder component produced by the actuator is complete.

14. A method of controlling position, comprising:
activating an actuator coupled to a position encoder component to produce a change in position of the position encoder component, wherein the position encoder component comprises a magnetic region configured to produce a magnetic field gradient from a first end of the magnetic region to the second end of the magnetic region;
determining a direction and magnitude of the change in position of the position encoder component based on the output of a first magnetic field sensor and a second magnetic field sensor, wherein the first magnetic field sensor and the second magnetic field sensor are separated by a distance that is less than a length of the magnetic region; and
deactivating the actuator to stop the change in position of the position encoder component when a desired position of the position encoder component is reached.

15. The method of claim 14, further comprising determining the position of the position encoder element after deactivating the actuator.

16. A position sensor, comprising:
a first magnetic field sensor,
a second magnetic field sensor, and
a position encoder component comprising a plurality of uniform magnetic regions, wherein the uniform magnetic regions have a uniform spacing therebetween,
wherein the first magnetic field sensor and the second magnetic field sensor are separated by a distance that is less than the uniform spacing between the uniform magnetic regions.

17. The position sensor of claim 16, wherein at least one of the first magnetic sensor and the second magnetic sensor comprise a nitrogen vacancy (NV) diamond magnetic field sensor.

18. The position sensor of claim 16, further comprising a third magnetic field sensor and a fourth magnetic field sensor.

19. The position sensor of claim 16, wherein the position encoder component is a rotary position encoder.

20. The position sensor of claim 16, wherein the position encoder component is a linear position encoder.

21. The position sensor of claim 16, wherein the position encoder component further comprises a magnetic region configured to produce a magnetic field gradient from a first end of the magnetic region to the second end of the magnetic region disposed between each of the plurality of uniform magnetic regions.

22. The position sensor of claim 16, wherein the magnetic region comprises a ferromagnetic component having a cross-section at the first end of the magnetic region that is smaller than a cross-section at the second end of the magnetic region.

23. The position sensor of claim 16, wherein the magnetic region comprises a magnetic polymer having a magnetic particle concentration at the first end of the magnetic region that is smaller than a magnetic particle concentration at the second end of the magnetic region.

24. A position sensor system, comprising:
a position encoder component comprising a plurality of uniform magnetic regions, wherein the uniform magnetic regions have a uniform spacing therebetween,
a first magnetic field sensor,
a second magnetic field sensor, wherein the first magnetic field sensor and the second magnetic field sensor are separated by a distance that is less than the uniform spacing between the uniform magnetic regions, and
a controller configured to:
determine a direction and magnitude of a change in position of the position encoder component based on the output of the first magnetic field sensor and the second magnetic field sensor.

25. The position sensor system of claim 24, wherein the controller is further configured to determine a position of the position encoder component based on an initial position of the position encoder component and the direction and magnitude of the change in position of the position encoder component.

26. A position control system, comprising:
a position encoder component comprising a plurality of uniform magnetic regions, wherein the uniform magnetic regions have a uniform spacing therebetween,
an actuator coupled to the position encoder component,
a first magnetic field sensor,
a second magnetic field sensor, wherein the first magnetic field sensor and the second magnetic field sensor are separated by a distance that is less than the uniform spacing between the uniform magnetic regions, and
a controller configured to:
control the actuator to produce a change in position of the position encoder component,
determine a direction and magnitude of the change in position of the position encoder component based on the output of the first magnetic field sensor and the second magnetic field sensor.

27. The position control system of claim 26, wherein the controller is further configured to control the actuator to stop a change in position of the position encoder component when a desired change in position of the position encoder component has been achieved.

28. The position control system of claim 26, wherein the controller is further configured to determine the position of the position encoder component after the change in position of the position encoder component produced by the actuator is complete.

29. A method of controlling position, comprising:
activating an actuator coupled to a position encoder component to produce a change in position of the position encoder component, wherein the position encoder component comprises a plurality of uniform magnetic regions, wherein the uniform magnetic regions have a uniform spacing therebetween;
determining a direction and magnitude of the change in position of the position encoder component based on the output of a first magnetic field sensor and a second magnetic field sensor, wherein the first magnetic field sensor and the second magnetic field sensor are separated by a distance that is less than the uniform spacing between the uniform magnetic regions; and
deactivating the actuator to stop the change in position of the position encoder component when a desired position of the position encoder component is reached.

30. The method of claim 29, further comprising determining the position of the position encoder element after deactivating the actuator.

31. A position sensor, comprising:
a first magnetic field sensor,
a second magnetic field sensor, and
a position encoder component comprising a plurality of uniform magnetic regions and a plurality of tapered magnetic regions,
wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions.

32. The position sensor of claim 31, wherein at least one of the first magnetic sensor and the second magnetic sensor comprise a nitrogen vacancy (NV) diamond magnetic field sensor.

33. The position sensor of claim 31, wherein the tapered magnetic regions comprise a ferromagnetic component having a cross-section at the first end of the tapered magnetic regions that is smaller than a cross-section at the second end of the tapered magnetic regions.

34. The position sensor of claim 31, wherein the tapered magnetic regions comprise a magnetic polymer having a magnetic particle concentration at the first end of the tapered magnetic regions that is smaller than a magnetic particle concentration at the second end of the tapered magnetic regions.

35. The position sensor of claim 31, further comprising a third magnetic field sensor and a fourth magnetic field sensor.

36. The position sensor of claim 31, wherein the position encoder component is a rotary position encoder.

37. The position sensor of claim 31, wherein the position encoder component is a linear position encoder.

38. A position sensor system, comprising:
a position encoder component comprising a plurality of uniform magnetic regions and a plurality of tapered magnetic regions, wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions,
a first magnetic field sensor,
a second magnetic field sensor, wherein the first magnetic field sensor and the second magnetic field sensor are separated by a distance that is less than the uniform spacing between the uniform magnetic regions, and
a controller configured to:
determine a direction and magnitude of a change in position of the position encoder component based on the output of the first magnetic field sensor and the second magnetic field sensor.

39. The position sensor system of claim 38, wherein the controller is further configured to determine a position of the position encoder component based on an initial position of the position encoder component and the direction and magnitude of the change in position of the position encoder component.

40. A position control system, comprising:
a position encoder component comprising a plurality of uniform magnetic regions and a plurality of tapered magnetic regions, wherein the uniform magnetic regions have a uniform distance therebetween, the tapered magnetic regions are configured to produce a magnetic field gradient from a first end of the magnetic region to the second end of the magnetic region, and the spacing between the first magnetic field sensor and the second magnetic field sensor is less than the distance between the uniform magnetic regions,
an actuator coupled to the position encoder component,
a first magnetic field sensor,
a second magnetic field sensor, wherein the first magnetic field sensor and the second magnetic field sensor are separated by a distance that is less than the uniform spacing between the uniform magnetic regions, and
a controller configured to:
control the actuator to produce a change in position of the position encoder component,
determine a direction and magnitude of the change in position of the position encoder component based on the output of the first magnetic field sensor and the second magnetic field sensor.

41. The position control system of claim 40, wherein the controller is further configured to control the actuator to stop a change in position of the position encoder component when a desired change in position of the position encoder component has been achieved.

42. The position control system of claim 40, wherein the controller is further configured to determine the position of the position encoder component after the change in position of the position encoder component produced by the actuator is complete.

43. A method of controlling position, comprising:
activating an actuator coupled to a position encoder component to produce a change in position of the position encoder component, wherein the position encoder component comprises a plurality of uniform magnetic regions and a plurality of tapered magnetic regions, wherein the uniform magnetic regions have a uniform distance therebetween, and the tapered magnetic regions are configured to produce a magnetic field gradient from a first end of the magnetic region to the second end of the magnetic region;
determining a direction and magnitude of the change in position of the position encoder component based on the output of a first magnetic field sensor and a second magnetic field sensor, wherein the first magnetic field sensor and the second magnetic field sensor are separated by a distance that is less than the uniform spacing between the uniform magnetic regions; and
deactivating the actuator to stop the change in position of the position encoder component when a desired position of the position encoder component is reached.

44. The method of claim 43, further comprising determining the position of the position encoder element after deactivating the actuator.
